(19) United States
(12) Patent Application Publication
(10) Pub. No.: US 2025/0124180 A1
(43) Pub. Date: Apr. 17, 2025

(54) JUST-IN-TIME SAFETY SYSTEMS

(71) Applicant: Siemens Corporation, Washington, DC (US)

(72) Inventor: Laszlo Nemeth, Hoboken, NJ (US)

(73) Assignee: Siemens Corporation, Washington, DC (US)

(21) Appl. No.: 18/682,139

(22) PCT Filed: Aug. 31, 2021
(86) PCT No.: PCT/US2021/048316

§ 371 Date: Feb. 8, 2024

(51) Int. Cl. G06F 30/17

(52) U.S. Cl. CPC G06F 30/17

(57) ABSTRACT

Methods and systems are disclosed for generating or monitoring programmatically accessible safety requirements dynamically during a systems lifecycle. In an example aspect, a safety computing system includes one or more processors and a memory having a plurality of application modules stored thereon. The modules can include an ontology and reasoning engine configured to update safety-related ontologies related to components of a robotics or automation system throughout the systems lifecycle. The safety computing system can further include a design module, an implementation module, and an operations module each communicatively coupled to the ontology and reasoning engine.

### BACKGROUND

Engineering design of various systems generally begins with user or stakeholder requirements. In some cases, requirements come from a customer. Requirements can include a list of functions that a particular system needs to perform. Requirements can also indicate details of an environment of the system that is being designed. Further still, requirements often include safety aspects related to the system. Such safety aspects or safety requirements are often extracted by a safety engineer from regulations and procedures. From such regulations and procedures, the safety engineer can produce a safety requirements specification (SRS) document that is dependent on the functionality of environment. The SRS document can guide or inform various phases of the lifecycle of a given system, such as system design, system implementation, system operation, system maintenance, and decommissioning of the system.

It is recognized herein that current SRS documents are static such that system safety has to be re-established before functionality of the system can be changed or the environment of the system can be changed. It is further recognized herein that enforcing static SRS documents can inhibit, for instance prevent, verification of various requirements and safety limits during operation. For example, in some case, static requirements can limit or prevent changes that violate the static requirements. By way of example, if a given static requirement indicates that a user is kept one (1) meter from a given machine, the static requirement might prevent the user from being kept two (2) meters from the given machine.

### SUMMARY

Methods and systems are disclosed for generating or maintaining programmatically accessible safety requirements dynamically during a system's lifecycle. In an example aspect, a safety computing system includes one or more processors and a memory having a plurality of application modules stored thereon. The modules can include an ontology and reasoning engine configured to update safety-related ontologies related to components of a robotics or automation system throughout the system's lifecycle. The safety computing system can further include a design module, an implementation module, and an operations module each communicatively coupled to the ontology and reasoning engine. Various operations can be performed by the safety computing system. For example, the system can obtain or receive a safety requirements specification. The safety requirements specification can define safety constraints based on user requirements and standards associated with a robotics or automation system. During design of the robotics or automation system, the ontology and reasoning engine can receive a selection indicative of a component (e.g., machine, robot, etc.) associated with a design of the robotics or automation system. Such selections can be received from the design module or implementation module. Based on the component and the safety constraints, the ontology and reasoning engine can determine one or more safety aspects associated with the component. By way of example, and without limitation, safety aspects might relate to distances between a robot and other objects or humans, speeds of a robot, or any other operating parameters related to safety that might depend on the environment. The ontology and reasoning engine can receive at least one decision related to the one or more safety aspects associated with the component. Such a decision can be received from the design module. Based on the at least one decision, the ontology and reasoning engine can update an ontology associated with the component.

### BRIEF DESCRIPTION OF THE DRAWINGS

The foregoing and other aspects of the present invention are best understood from the following detailed description when read in connection with the accompanying drawings. For the purpose of illustrating the invention, there is shown in the drawings embodiments that are presently preferred, it being understood, however, that the invention is not limited to the specific instrumentalities disclosed. Included in the drawings are the following Figures:

FIG. 1 is a block diagram of a current approach to safety engineering that relates to a waterfall model.

FIG. 2 is a block diagram of a safety computing system in accordance with an example embodiment, wherein the safety computing system can be configured to generate safety constraints that can be verified just-in-time (e.g., before the relevant safety operation takes place) throughout the lifecycle of a given robotics or automaton system.

FIG. 3 is a call flow that depicts example operations that can be performed by the safety computing system illustrated in FIG. 2 that can include an ontology and reasoning engine communicatively coupled to a design module, an implementation module, and an operations module.

FIG. 4 shows an example of a computing environment within which embodiments of this disclosure may be implemented.

### DETAILED DESCRIPTION

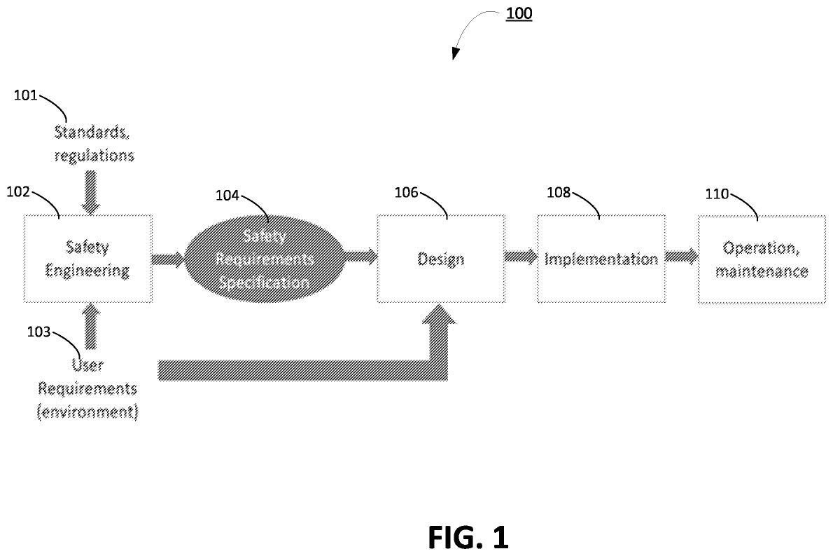

As an initial matter, it is recognized herein that current approaches to safety design for systems, such as robotics or automation systems, rely on a safety requirements specification (SRS) document that is statically enforced during the lifecycle of a particular system. For example, the lifecycle of a system can include design, implementation, operation, and maintenance. It is further recognized herein that such static enforcement can limit flexibility during operation, which, in some cases, can make certain robotics or automation practices cost-prohibitive for small and medium enterprises, among others. Referring to FIG. 1, an example design process 100 illustrates current practices for safety design, which generally aligns with the waterfall model in software engineering. The waterfall model in software engineering generally refers the life cycle of a system in which the various stages of design, implementation, and development are strictly sequential. In particular, for example, at 102, a safety engineer performs safety engineering that results in an SRS document 104. Inputs to the safety engineering at 102 can include standards and regulations 101 and user or stakeholder requirements 103. By way of example, standards and regulations 101 may relate to machines, plants, users, or the like. By way of further example, a standard related to a particular machine may stipulate electrical requirements for operating the machine. Examples of safety requirements, or standards and regulations 101, further include training requirements for workers or requirements associated with a particular work piece. By way of example, workers might required to wear a badge (e.g., which is readable electronically like Bluetooth) by the system. If the worker does not have the prescribed qualification (e.g., indicated by the badge), the robot might be inoperable or required to not move. By way of another example, the safety requirements might indicate that a particular workpiece cannot be heavier than a certain weight. Alternatively, or additionally, an expensive work piece might have a requirement associated with it that indicates that the work piece cannot be dropped. By way of yet another example, a safety requirement might indicate that a robot cannot spray a particular chemical within a certain distance of a human.

The user or stakeholder requirements 103 generally describe what the system needs to perform to produce a given product or output. For examples, the user requirements 103 can stipulate throughput, response times, performance metrics, resource constraints, or the like. In some cases, the user requirements 103 can define an environment in which the system operates, such as, for example, an environment having a particular humidity range or temperature range. At 106, the system is designed based on the SRS document 104 and the user requirements 103. With continuing reference to FIG. 1, after the system is designed at 106, the system is implemented at 108. After the system is implemented at 106, the system is operated and maintained at 110. Thus, as illustrated in FIG. 1, in current approaches the SRS document remains the same throughout the lifecycle of the system. If there are changes during the operation 110, the entire development lifecycle is restarted. For example, if the environment changes so that there are now sharp objects present in the environment, when the original SRS document did not contemplate sharp objects, the safety engineer updates the SRS, the designers update the design based on the updated SRS, and the implementors change their code so that the system can resume operations. It is recognized herein that this process is burdensome in terms of time and expense, among other things.

In accordance with various embodiments described herein, however, safety requirements in an SRS document or the like can be dynamically adjusted and satisfied throughout operation of flexible systems, for instance systems in the automation and robotics domain. For example, the verification of safety requirements can be delayed until operation (e.g., just-in-time) to reduce engineering time as demand varies, products vary, or the environment varies (e.g., collaborative environment having humans present). Without being bound by theory, small and medium enterprises (SMEs), among others, often include automation systems with varying demand, which can result in frequent changes among products (e.g., dimensions, weight) and quantities. Such variability is an example reason of why the design and implementation of systems can be difficult and costly if safety requirements are not agile and dynamic.

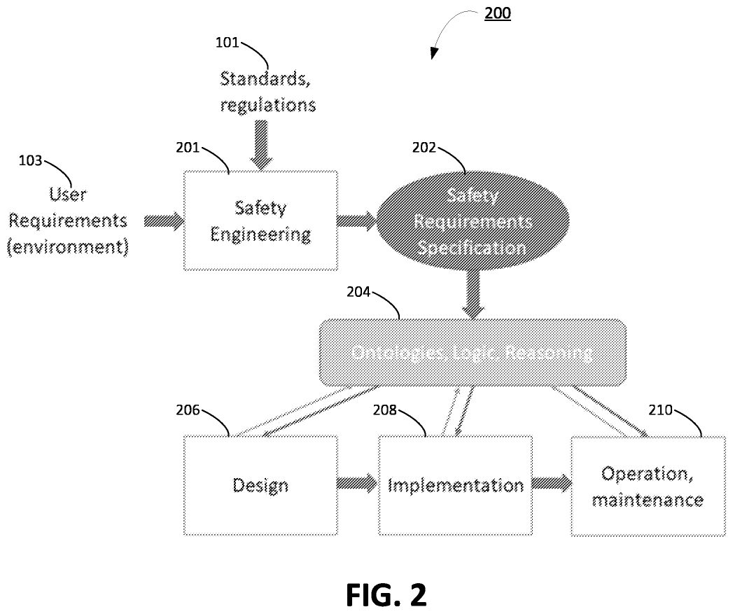

Referring now to FIG. 2, an example safety computing system 200 can be configured to dynamically adjust safety aspects of a system (e.g., robotics automation systems) such that standards, requirements, component limitations, and SRS documents, for instance an SRS document 202, are formalized and programmatically accessible throughout the system lifecycle. The SRS 202 can define rules and current standards, and the current environment can define facts. From the facts, the safety and computing system 200, in particular an ontology and reasoning engine 204, can determine whether a particular operation is safe. Thus, the safety computing system 200 can generate rules concerning how to verify safety, and can enable the rules to be checked during operation.

The system lifecycle can include design, implementation operation, maintenance, repurposing, and decommissioning. The safety computing system 200 can include one or more processors and memory having stored thereon applications, agents, and computer program modules including, for example, the ontology and reasoning engine 204, a design module 206, an implementation module 208, and an operations module 210. Each of the design module 206, implementation module 208, and operation module 210 can be communicatively coupled to the ontology and reasoning engine 204. For example, the ontology and reasoning engine 204 can be configured to monitor the design module 206, implementation module 208, and operations module 210. It will be appreciated that the program modules, applications, computer-executable instructions, code, or the like depicted in FIG. 2 are merely illustrative and not exhaustive, and that processing described as being supported by any particular module may alternatively be distributed across multiple modules or performed by a different module. In addition, various program module(s), script(s), plug-in(s), Application Programming Interface(s) (API(s)), or any other suitable computer-executable code may be provided to support functionality provided by the program modules, applications, or computer-executable code depicted in FIG. 2 and/or additional or alternate functionality. Further, functionality may be modularized differently such that processing described as being supported collectively by the collection of program modules depicted in FIG. 2 may be performed by a fewer or greater number of modules, or functionality described as being supported by any particular module may be supported, at least in part, by another module. In addition, program modules that support the functionality described herein may form part of one or more applications executable across any number of systems or devices in accordance with any suitable computing model such as, for example, a client-server model, a peer-to-peer model, and so forth. In addition, any of the functionality described as being supported by any of the program modules depicted in FIG. 2 may be implemented, at least partially, in hardware and/or firmware across any number of devices.

Still referring to FIG. 2, in various examples, safety engineering 201 is performed based on the user requirements or stakeholder requirements 103 and the standards and regulations 101. User requirement and stakeholder requirements can be used interchangeably herein, without limitation, unless otherwise specified. By way of example, a marketing department can define stakeholder, in particular when they identify a particular part (e.g., ball bearings) for purchase. Continuing with the ball bearing example, a mechanical engineer might specify the precise material and tolerance for the ball bearings, thus that person can also define a stakeholder. Further still, an accountant can define a stakeholder, for instance by instituting a price cap on the ball bearings. Quality control can also mandate requirements on the ball bearings. Stakeholders can be weighted differently. By way of further example, mechanical engineers might add that the product that includes the ball bearings ends will be used in a humidity controlled environment, and the humidity must be within 10% and 30%. Such a restriction can define a requirement on the user of their product for warranty and safety purposes. Thus, requirements can be backwards (imposes requirements on the supplier of the ball bearings) or forwards (imposes a requirement on the final user). Thus, requirements in general can be classified as functional requirements that describe what the ball bearings (or a system) needs to do (e.g., a chair must be able to support one person in the seating position), or as non-functional requirements that prescribe other properties of the system (e.g., the chair must be blue and the comfortable). Safety requirements can define non-functional requirements. Other example non-functional requirements include security and performance.

For example, based on the user requirements 103, the relevant safety requirements and standards can be identified, for instance by a safety engineer or the safety computing system 200. In some cases, the standards can be obtained automatically via programs. As a result of the safety engineering 201, the SRS document 202 can be generated. In particular, the stakeholder requirements and the regulations can be combined and transformed into a representation that is programmatically accessible (which can define the ontology of the system) during the entire lifecycle. The SRS document 202 can be sent to, or otherwise accessible by, the ontology and reasoning engine 204.

As described herein, various phases of a system's lifecycle can interact with the safety ontologies and the reasoning engine 204 differently. For example, during system design in the design module 206, an engineer might insert a component in a computer-aided design (CAD) tool of the like. The component might represent a part of a system design or a particular machine (e.g., robot) for performing an operation related to the system. Based on the component, the ontology and reasoning engine 204 can determine limitations and safety aspects associated with the component.

By way of example, suppose the safety SRS 202 includes a rule that robots must maintain a minimum distance from a human (e.g., this rule may originate from the regulations 101). In the example, the designer decides to have a cage around the robot. As long as the distance of the cage to the robot is larger than the minimum distance between the robot and the human as required by the SRS 202, the requirement is satisfied. It can be assumed that the human is not going to climb over the cage. If the designer is more cautious the designer could implement the cage and a motion detector inside the cage. But installing the motion detector can impose a requirement on the implementation via a rule ‘if you have a motion detector you must check that it is not signaling the presence of a human’. Consequently, the code for this application might return an error from the programming environment if such a check is not implemented. The programming environment that can return the error can originate from the ontology and reasoning engine 204.

Thus, the ontology and reasoning engine 204 can return the limitations and the safety relevant aspects of the component to the design module 206. In some cases, the design module 206 can require, for instance via an indication in the CAD tool or the like, the engineer or designer to address one or more safety aspects associated the given component, as in the cage example mentioned above. In some examples, there might be more than one choice or addressing a given safety aspect, and after the designer selects one of the choices, the design module 206 can return the selection to the ontology and reasoning engine 204 so that the selection becomes part of the state of the ontology associated with the component. The ontology associated with a given component can indicate the properties or relationships associated with the component. Thus, a designer can impose further requirements downstream to the implementation module 208. Alternatively, or additionally, the implementation module 208 can determine that a requirement cannot be satisfied without a design change. The implementation module 208 can signal such a determination to the design module 206 through the ontology. For example, the implementation module 208 might signal that the design module 208 needs to add more safety sensors. Such a signal can take place through the ontology, for instance via the ontology and reasoning engine 204.

For example, the ontology of a given component, for instance a machine, might indicate that the component requires a safe distance between humans and the machine during its operation. Thus, when the given component is identified by the ontology and reasoning engine 204, the ontology and reasoning engine 204 can return various safe distances or safety aspects associated with the component. In particular, the ontology and reasoning engine 204 can return different distances that correspond to respective decisions. Thus, the safe distances may vary based on decisions made at the design module 206. Further, the ontology and reasoning engine 204 might determine whether an object has sufficient sharpness to define a hazard to a human, which can affect other decisions related to mitigating the risk, such as orientation of the sharp object (e.g., turned away from human) or distances during operation. For example, an engineer may decide to insert a physical barrier between the component and humans, which may reduce, for instance eliminate, the safe distance that is required between the component and humans. Thus, in an example, inserting a physical barrier might pose no further constraints on the implementation or operation of the machine. Alternatively, the engineer might select a light curtain for insertion between the machine and humans. Based on this decision, the safe distance indicated by the ontology and reasoning engine 206 might be greater than the distance required if a different physical barrier is selected, but less than the safe distance required if nothing is inserted between the machine and humans. The decision can be returned by the design module 206 to the ontology and reasoning engine 206. Based on the returned decision, the ontology and reasoning engine 206 can update the ontology associated with the component. Further, responsive to the decision, the ontology and reasoning engine 204 can impose a constraint (e.g., safe distance) on the implementation module 208. Continuing with the example, if the light curtain is selected, the implementation module 208 can call a function to check whether the light curtain is working. If light curtain is not operating properly, the operation module 210 can determine this during a check that is performed according to code that can be inserted by the implementation module 208. Thus, this check can occur at the last moment before the curtain is used, so as to define a just-in-time safety operation.

By way of further example, during implementation, if a developer, and thus the implementation module 208, calls a function that makes a robot move, or a function that controls a device attached to a programmable logic controller (PLC), a compiler of the implementation module 208 can interact with the ontology and reasoning engine 204 so as to determine whether safety aspects related to the robot are addressed. When the ontology and reasoning engine 204 determines that a safety aspect, for instance a safety constraint, is out of compliance, the ontology and reasoning engine 204 can issue warnings or errors depending on the safety violation. In particular, returning to the light curtain example above, the compiler of the implementation module 208 can issue an error if there are no calls to verify that the light curtain is functioning properly. In some cases, the implementation module 208 can pose a constraint on the design module 208, via the ontology and reasoning engine 204, for instance when a safety requirement is not verifiable by the compiler. In some cases, if it is not verifiable by the complier, the ontology (ontology and reasoning engine 204) can record this so that a designer can act. If the designer does not act, for example, during operation the ontology and reasoning engine 204 can indicate that the operation is unsafe and should be checked. Returning again to the light curtain example, the implementation module 208 might determine that the required safe distance associated with the light curtain is not possible to implement, for instance because of spatial implementations imposed by the associated environment or the like. Based on this determination, the implementation module 208 can pose a constraint associated with the component to the ontology and reasoning engine 204, and the constraint can be provided to the design module 208. Such a flow of constraints is an example of constraints flowing backwards in the system 200, for instance from the implementation module 208 to the design module 206. As an example, the constraint might stipulate that a physical (e.g., immovable) barrier is placed between the component and humans. Thus, as described herein, constraints can flow forwards (e.g., from the design module toward the operation module 210) and backwards (e.g., from the operation module 210 toward the design module 206) in the safety computing system 200.

With continuing reference to FIG. 2, during operation, the operation module 210 can access the ontology and reasoning engine 204 such that safety constraints can be verified or checked during operation of the automation or robotics system. Such constraints can result from, for example, the original user requirements 103, the design module 206 (e.g., via design choices), or the implementation module 208 (e.g., via implementation decisions). During operation (or runtime), in some cases, if the operations module 210 determines that a safety requirement or constraint is not met, the operations module 210 can take action. Example actions include, without limitation, stopping operation of the system or reporting the unsatisfied requirement to an operator of the system.

In some examples, if an unsatisfied requirement occurs during operation, a safety violation can be identified and the operation can be stopped. Furthermore, the incident can be recorded in the ontology, which can also be amended by the design module 206 or the implementation module 208.

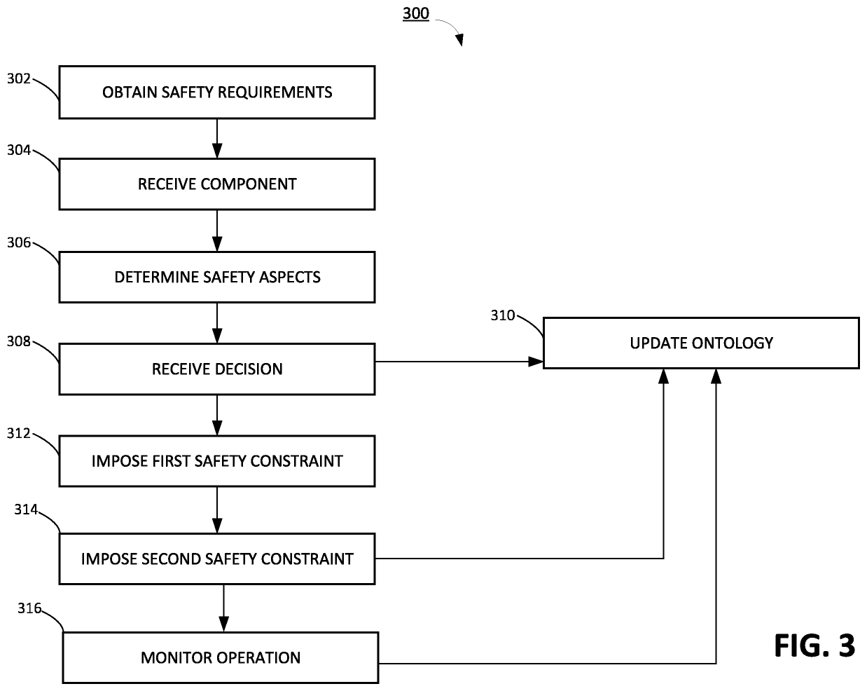

Referring now to FIG. 3, various operations, for instance example operations 300, can be performed by the just-in-time safety systems such as the safety computing system 200. For example, at 302, the system 200, in particular the ontology and reasoning engine 204, can obtain or receive a safety requirements specification. The safety requirements specification can define safety constraints based on user requirements and standards associated with a robotics or automation system. At 304, during design of the robotics or automation system, the ontology and reasoning engine 204 can receive a selection indicative of a component (e.g., machine, robot, etc.) associated with a design of the robotics or automation system. Such selections can be received from the design module 206. At 306, based on the component and the safety constraints, the ontology and reasoning engine 204 can determine one or more safety aspects associated with the component. By way of example, and without limitation, safety aspects might relate to distances between a robot and other objects or humans, speeds of a robot, or any other operating parameters related to safety that might depend on the environment. At 308, the ontology and reasoning engine 204 can receive at least one decision related to the one or more safety aspects associated with the component. Such a decision can be received from the design module 206. At 310, based on the at least one decision, the ontology and reasoning engine 204 can update an ontology associated with the component.

With continuing reference to FIG. 3, at 312, in response to the decision, the design module 206, via the ontology and reasoning engine 304, can impose a first safety constraint on the implementation module 208 that is configured to implement the design of the robotics or automation system. For example, based on the first safety constraint, and during implementation of the design of the robotics or automation system, the implementation module 208 can call a function to determine whether a physical device associated with the component is working in accordance with the first safety constraint. By way of example, and without limitation, the first safety constraint might relate to placing a light barrier (physical device) between a robot (component) and a humans in a collaborative environment, and the function might verify that the light barrier is functioning properly so as to be disposed in the proper position. In some cases, during implementation of the design of the robotics or automation system, the implementation module 208 might make a determination that the physical device associated with the component is not working in accordance with the first safety constraint. Based on the determination, at 314, the implementation module 208 (via the ontology and reasoning engine 204) can impose a second safety constraint on the design module 206 that is configured to generate the design of the robotics or automation system. The second safety constraint also can be associated with the component. By way of example, and without limitation, the second safety constraint may require that the robot is not carrying anything sharp, travels at a reduced speed, or that different barrier is placed between the robot and humans, because the first safety constraint (e.g., light barrier) is not working. Additionally, or alternatively, based on the determination, the ontology can be updated (at 310). At 316, the operation module 210 can monitor operation of the robotics or automation system. In particular, during operation of the robotics or automation system, the operation module 210 can determine whether the component is operating in accordance with the second safety constraint. In some cases, when the component is not operating in accordance with the second safety constraint, the operation module 210 can stop operation of the robotics or automation system. Further, based on the monitoring the operations, the operation module 210 can also update the ontology of the component (at 310).

Thus, the safety requirements can define combinations of general rules (e.g., sharp objects are hazardous), safety-specific rules (e.g., minimum distance between humans and the robot is X), and characteristics of the environment. Given the rules and the characteristics the reasoning engine 204 can deduce/derive more facts (e.g., compute the consequences of the rules). The design module 206 can add more facts because each design decision can narrow down the possible implementations (e.g., if the designer adds a cage then no implementation is possible that does not include a cage). More facts allow the reasoning engine 204 to derive more facts (e.g., certain aspects are now satisfied). The implementation module 208 can also add facts, so the reasoning engine 204 computes even more facts. In various examples, at some point, the collection of the facts satisfy all the requirements.

As described herein, in accordance with various embodiments, safety-related constraints can flow throughout the lifecycle of a given system. In some cases, the flow of constraints that arise during the lifecycle are controlled by a safety policy. For example, a first or relaxed safety policy may identify a subset of constraints that hold once they are satisfied. For example, adding a physical barrier may be included in the subset, such that once the physical barrier is added, the system can assume that the barrier remains in place. Alternatively, or additionally, a second or paranoid policy might identify a subset of constraints that require checks. For example, if the physical barrier is governed by the second policy, the design module 206 might add a sensor to the system and require that the sensor check (e.g., periodically or in response to an event) that the physical barrier is still in place. In particular, for example, a constraint might require that an appropriate function call verifies the status of the sensor during operation. In some examples, the policy that governs a given constraint can be changed at any time, for instance during operation.

Without being bound by theory, embodiments described herein, for instance the safety computing system 200, define just-in time safety systems that can separate safety concerns related to a robotics or automation system from performance metrics (correctness) of the design of the robotics or automation system. Further, the safety computing system 200 can include the ontology and reasoning module 204 that is communicatively coupled to the design module 208, implementation module 208, and the operations module 210, such that safety-related information can be maintained in logically consistent form through the lifecycle of the associated robotics or automation system. Such a configuration can reduce burdens on designers, implementors, and operation teams as compared current to waterfall approaches to safety design. Further, when a given robotics or automation system is adapted to a different environment, for instance when new user requirements 103 are received, the system 200 can adapt more quickly as compared to a system designed in accordance with the waterfall model, thereby shortening the safety review cycle.

Embodiments described herein can define full requirements traceability, such that the system 200 can control safety-related aspects of a given robotics or automation system. For example, in some cases, safety requirements can be traced to code and verified in code. Additionally, or alternatively, safety requirements can be traced and verified during operation, for instance while producing a final product, such that a fault that is detected during operation can be traced back to the requirements 103 or the standards 101. Traceability can be defined by the ontology. The ontology and reasoning engine 204 receives facts added by the design module 206 or implementation module 208, such that the facts can be traced to their origin. Thus, in various examples, each requirement can be connected with the original stakeholder and each fact can be annotated with its origin and its support (e.g., whether it was added in response to a particular requirement.

Thus, as described herein, just-in time safety systems, such as the safety computing system 200, can address safety requirements at any point during the design, implementation, or runtime of a given system so as to ensure operations are performed safely. Further, in accordance with various embodiments, systems can be safely modified, for instance to meet varying demand, varying products (e.g., different sizes, weights), or varying environments (e.g., co-located or collaborative environments).

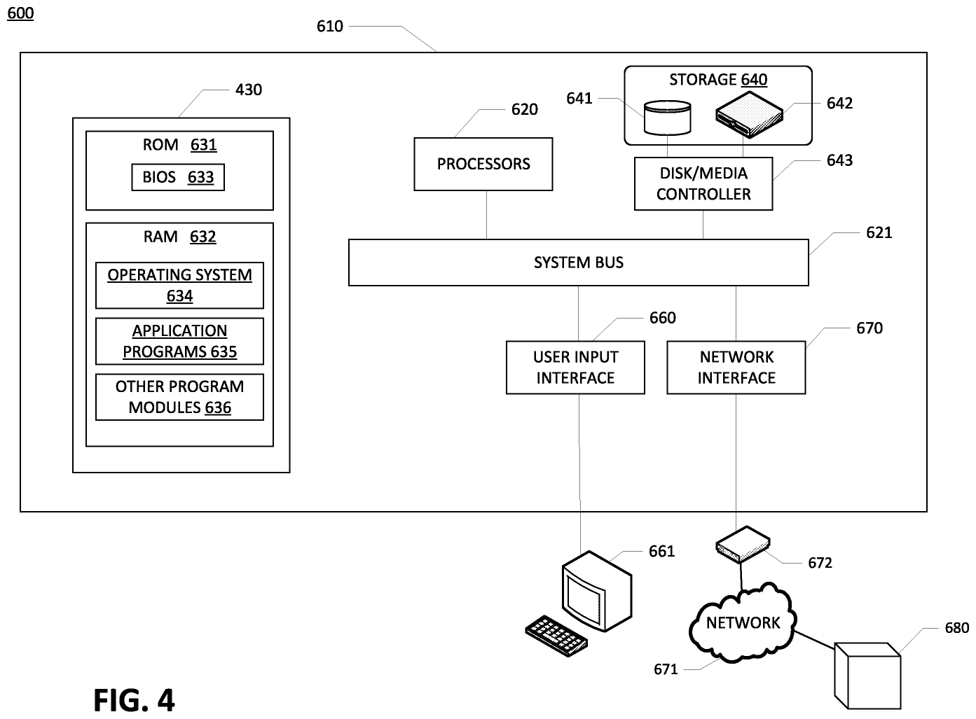

FIG. 4 illustrates an example of a computing environment within which embodiments of the present disclosure may be implemented. A computing environment 600 includes a computer system 610 that may include a communication mechanism such as a system bus 621 or other communication mechanism for communicating information within the computer system 610. The computer system 610 further includes one or more processors 620 coupled with the system bus 621 for processing the information. The safety computing system 200 may include, or be coupled to, the one or more processors 620.

The processors 620 may include one or more central processing units (CPUs), graphical processing units (GPUs), or any other processor known in the art. More generally, a processor as described herein is a device for executing machine-readable instructions stored on a computer readable medium, for performing tasks and may comprise any one or combination of, hardware and firmware. A processor may also comprise memory storing machine-readable instructions executable for performing tasks. A processor acts upon information by manipulating, analyzing, modifying, converting or transmitting information for use by an executable procedure or an information device, and/or by routing the information to an output device. A processor may use or comprise the capabilities of a computer, controller or microprocessor, for example, and be conditioned using executable instructions to perform special purpose functions not performed by a general purpose computer. A processor may include any type of suitable processing unit including, but not limited to, a central processing unit, a microprocessor, a Reduced Instruction Set Computer (RISC) microprocessor, a Complex Instruction Set Computer (CISC) microprocessor, a microcontroller, an Application Specific Integrated Circuit (ASIC), a Field-Programmable Gate Array (FPGA), a System-on-a-Chip (SoC), a digital signal processor (DSP), and so forth. Further, the processor(s) 620 may have any suitable microarchitecture design that includes any number of constituent components such as, for example, registers, multiplexers, arithmetic logic units, cache controllers for controlling read/write operations to cache memory, branch predictors, or the like. The microarchitecture design of the processor may be capable of supporting any of a variety of instruction sets. A processor may be coupled (electrically and/or as comprising executable components) with any other processor enabling interaction and/or communication there-between. A user interface processor or generator is a known element comprising electronic circuitry or software or a combination of both for generating display images or portions thereof. A user interface comprises one or more display images enabling user interaction with a processor or other device.

The system bus 621 may include at least one of a system bus, a memory bus, an address bus, or a message bus, and may permit exchange of information (e.g., data (including computer-executable code), signaling, etc.) between various components of the computer system 610. The system bus 621 may include, without limitation, a memory bus or a memory controller, a peripheral bus, an accelerated graphics port, and so forth. The system bus 621 may be associated with any suitable bus architecture including, without limitation, an Industry Standard Architecture (ISA), a Micro Channel Architecture (MCA), an Enhanced ISA (EISA), a Video Electronics Standards Association (VESA) architecture, an Accelerated Graphics Port (AGP) architecture, a Peripheral Component Interconnects (PCI) architecture, a PCI-Express architecture, a Personal Computer Memory Card International Association (PCMCIA) architecture, a Universal Serial Bus (USB) architecture, and so forth.

Continuing with reference to FIG. 4, the computer system 610 may also include a system memory 630 coupled to the system bus 621 for storing information and instructions to be executed by processors 620. The system memory 630 may include computer readable storage media in the form of volatile and/or nonvolatile memory, such as read only memory (ROM) 631 and/or random access memory (RAM) 632. The RAM 632 may include other dynamic storage device(s) (e.g., dynamic RAM, static RAM, and synchronous DRAM). The ROM 631 may include other static storage device(s) (e.g., programmable ROM, erasable PROM, and electrically erasable PROM). In addition, the system memory 630 may be used for storing temporary variables or other intermediate information during the execution of instructions by the processors 620. A basic input/output system 633 (BIOS) containing the basic routines that help to transfer information between elements within computer system 610, such as during start-up, may be stored in the ROM 631. RAM 632 may contain data and/or program modules that are immediately accessible to and/or presently being operated on by the processors 620. System memory 630 may additionally include, for example, operating system 634, application modules 635, and other program modules 636. Application modules 635 may include aforementioned modules described for FIG. 1 and may also include a user portal for development of the application program, allowing input parameters to be entered and modified as necessary.

The operating system 634 may be loaded into the memory 630 and may provide an interface between other application software executing on the computer system 610 and hardware resources of the computer system 610. More specifically, the operating system 634 may include a set of computer-executable instructions for managing hardware resources of the computer system 610 and for providing common services to other application programs (e.g., managing memory allocation among various application programs). In certain example embodiments, the operating system 634 may control execution of one or more of the program modules depicted as being stored in the data storage 640. The operating system 634 may include any operating system now known or which may be developed in the future including, but not limited to, any server operating system, any mainframe operating system, or any other proprietary or non-proprietary operating system.

The computer system 610 may also include a disk/media controller 643 coupled to the system bus 621 to control one or more storage devices for storing information and instructions, such as a magnetic hard disk 641 and/or a removable media drive 642 (e.g., floppy disk drive, compact disc drive, tape drive, flash drive, and/or solid state drive). Storage devices 640 may be added to the computer system 610 using an appropriate device interface (e.g., a small computer system interface (SCSI), integrated device electronics (IDE), Universal Serial Bus (USB), or FireWire). Storage devices 641, 642 may be external to the computer system 610.

The computer system 610 may include a user input interface or graphical user interface (GUI) 661, which may comprise one or more input devices, such as a keyboard, touchscreen, tablet and/or a pointing device, for interacting with a computer user and providing information to the processors 620.

The computer system 610 may perform a portion or all of the processing steps of embodiments of the invention in response to the processors 620 executing one or more sequences of one or more instructions contained in a memory, such as the system memory 630. Such instructions may be read into the system memory 630 from another computer readable medium of storage 640, such as the magnetic hard disk 641 or the removable media drive 642. The magnetic hard disk 641 and/or removable media drive 642 may contain one or more data stores and data files used by embodiments of the present disclosure. The data store 640 may include, but are not limited to, databases (e.g., relational, object-oriented, etc.), file systems, flat files, distributed data stores in which data is stored on more than one node of a computer network, peer-to-peer network data stores, or the like. Data store contents and data files may be encrypted to improve security. The processors 620 may also be employed in a multi-processing arrangement to execute the one or more sequences of instructions contained in system memory 630. In alternative embodiments, hard-wired circuitry may be used in place of or in combination with software instructions. Thus, embodiments are not limited to any specific combination of hardware circuitry and software.

As stated above, the computer system 610 may include at least one computer readable medium or memory for holding instructions programmed according to embodiments of the invention and for containing data structures, tables, records, or other data described herein. The term “computer readable medium” as used herein refers to any medium that participates in providing instructions to the processors 620 for execution. A computer readable medium may take many forms including, but not limited to, non-transitory, non-volatile media, volatile media, and transmission media. Non-limiting examples of non-volatile media include optical disks, solid state drives, magnetic disks, and magneto-optical disks, such as magnetic hard disk 641 or removable media drive 642. Non-limiting examples of volatile media include dynamic memory, such as system memory 630. Non-limiting examples of transmission media include coaxial cables, copper wire, and fiber optics, including the wires that make up the system bus 621. Transmission media may also take the form of acoustic or light waves, such as those generated during radio wave and infrared data communications.

Computer readable medium instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, may be implemented by computer readable medium instructions.

The computing environment 600 may further include the computer system 610 operating in a networked environment using logical connections to one or more remote computers, such as remote computing device 680. The network interface 670 may enable communication, for example, with other remote devices 680 or systems and/or the storage devices 641, 642 via the network 671. Remote computing device 680 may be a personal computer (laptop or desktop), a mobile device, a server, a router, a network PC, a peer device or other common network node, and typically includes many or all of the elements described above relative to computer system 610. When used in a networking environment, computer system 610 may include modem 672 for establishing communications over a network 671, such as the Internet. Modem 672 may be connected to system bus 621 via user network interface 670, or via another appropriate mechanism.

Network 671 may be any network or system generally known in the art, including the Internet, an intranet, a local area network (LAN), a wide area network (WAN), a metropolitan area network (MAN), a direct connection or series of connections, a cellular telephone network, or any other network or medium capable of facilitating communication between computer system 610 and other computers (e.g., remote computing device 680). The network 671 may be wired, wireless or a combination thereof. Wired connections may be implemented using Ethernet, Universal Serial Bus (USB), RJ-6, or any other wired connection generally known in the art. Wireless connections may be implemented using Wi-Fi, WiMAX, and Bluetooth, infrared, cellular networks, satellite or any other wireless connection methodology generally known in the art. Additionally, several networks may work alone or in communication with each other to facilitate communication in the network 671.

It should be appreciated that the program modules, applications, computer-executable instructions, code, or the like depicted in FIG. 4 as being stored in the system memory 630 are merely illustrative and not exhaustive and that processing described as being supported by any particular module may alternatively be distributed across multiple modules or performed by a different module. In addition, various program module(s), script(s), plug-in(s), Application Programming Interface(s) (API(s)), or any other suitable computer-executable code hosted locally on the computer system 610, the remote device 680, and/or hosted on other computing device(s) accessible via one or more of the network(s) 671, may be provided to support functionality provided by the program modules, applications, or computer-executable code depicted in FIG. 4 and/or additional or alternate functionality. Further, functionality may be modularized differently such that processing described as being supported collectively by the collection of program modules depicted in FIG. 4 may be performed by a fewer or greater number of modules, or functionality described as being supported by any particular module may be supported, at least in part, by another module. In addition, program modules that support the functionality described herein may form part of one or more applications executable across any number of systems or devices in accordance with any suitable computing model such as, for example, a client-server model, a peer-to-peer model, and so forth. In addition, any of the functionality described as being supported by any of the program modules depicted in FIG. 6 may be implemented, at least partially, in hardware and/or firmware across any number of devices.

It should further be appreciated that the computer system 610 may include alternate and/or additional hardware, software, or firmware components beyond those described or depicted without departing from the scope of the disclosure. More particularly, it should be appreciated that software, firmware, or hardware components depicted as forming part of the computer system 610 are merely illustrative and that some components may not be present or additional components may be provided in various embodiments. While various illustrative program modules have been depicted and described as software modules stored in system memory 630, it should be appreciated that functionality described as being supported by the program modules may be enabled by any combination of hardware, software, and/or firmware. It should further be appreciated that each of the above-mentioned modules may, in various embodiments, represent a logical partitioning of supported functionality. This logical partitioning is depicted for ease of explanation of the functionality and may not be representative of the structure of software, hardware, and/or firmware for implementing the functionality. Accordingly, it should be appreciated that functionality described as being provided by a particular module may, in various embodiments, be provided at least in part by one or more other modules. Further, one or more depicted modules may not be present in certain embodiments, while in other embodiments, additional modules not depicted may be present and may support at least a portion of the described functionality and/or additional functionality. Moreover, while certain modules may be depicted and described as sub-modules of another module, in certain embodiments, such modules may be provided as independent modules or as sub-modules of other modules.

Although specific embodiments of the disclosure have been described, one of ordinary skill in the art will recognize that numerous other modifications and alternative embodiments are within the scope of the disclosure. For example, any of the functionality and/or processing capabilities described with respect to a particular device or component may be performed by any other device or component. Further, while various illustrative implementations and architectures have been described in accordance with embodiments of the disclosure, one of ordinary skill in the art will appreciate that numerous other modifications to the illustrative implementations and architectures described herein are also within the scope of this disclosure. In addition, it should be appreciated that any operation, element, component, data, or the like described herein as being based on another operation, element, component, data, or the like can be additionally based on one or more other operations, elements, components, data, or the like. Accordingly, the phrase “based on,” or variants thereof, should be interpreted as “based at least in part on.”

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

What is claimed is:

1. A computer-implemented method of generating safety constraints associated with a robotics or automation system, the method comprising:
receiving a safety requirements specification, the safety requirements specification defining safety constraints based on user requirements and standards associated with the robotics or automation system;
during design of the robotics or automation system, receiving a selection, by an ontology and reasoning engine, indicative of a component associated with a design of the robotics or automation system;
based on the component and the safety constraints, the ontology and reasoning engine determining one or more safety aspects associated with the component;
the ontology and reasoning engine receiving at least one decision related to the one or more safety aspects associated with the component; and
based on the at least one decision, the ontology and reasoning engine updating an ontology associated with the component.

2. The method as recited in claim 1, the method further comprising:
responsive to the at least one decision, imposing a first safety constraint on an implementation module, the implementation module configured to implement the design of the robotics or automation system.

3. The method as recited in claim 2, the method further comprising:
during implementation of the design of the robotics or automation system, based on the first safety constraint, the implementation module calling a function to determine whether a physical device associated with the component is working in accordance with the first safety constraint.

4. The method as recited in claim 3, the method further comprising:
during implementation of the design of the robotics or automation system, making a determination that the physical device associated with the component is not working in accordance with the first safety constraint; and
based on the determination, imposing a second safety constraint on a design module, the second safety constraint associated with the component,
wherein the design module is configured to generate the design of the robotics or automation system.

5. The method as recited in claim 4, the method further comprising:
during operation of the robotics or automation system, determining whether the component is operating in accordance with the second safety constraint; and
when the component is not operating in accordance with the second safety constraint, stopping operation of the robotics or automation system.

6. A safety computing system comprising:
a memory having a plurality of application modules stored thereon; and
a processor for executing the application modules, the application modules comprising:
a design module configured to generate a design of a robotics or automation system;
an implementation module configured to implement the design of the robotics or automation system;
an operations module configured to monitor operation of the robotics or automation system; and
an ontology and reasoning engine communicatively coupled to the design module, implementation module, and the operations module, the ontology and reasoning engine configured to:
receive a safety requirements specification, the safety requirements specification defining safety constraints based on user requirements and standards associated with the robotics or automation system;
during design of the robotics or automation system, receive a selection indicative of a component associated with the design of the robotics or automation system;
based on the component and the safety constraints, determine one or more safety aspects associated with the component;
receive at least one decision related to the one or more safety aspects associated with the component; and
based on the at least one decision, update an ontology associated with the component.

7. The safety computing system as recited in claim 6, wherein the design module is further configured to, responsive to the at least one decision, impose a first safety constraint on the implementation module.

8. The safety computing system as recited in claim 7, wherein the implementation module is further configured to:
during implementation of the design of the robotics or automation system, based on the first safety constraint, call a function to determine whether a physical device associated with the component is working in accordance with the first safety constraint.

9. The safety computing system as recited in claim 8, wherein the implementation module is further configured to:
during implementation of the design of the robotics or automation system, make a determination that the physical device associated with the component is not working in accordance with the first safety constraint; and
based on the determination, impose a second safety constraint on the design module, the second safety constraint associated with the component.

10. The safety computing system as recited in claim 9, wherein the operations module is further configured to:
during operation of the robotics or automation system, determine whether the component is operating in accordance with the second safety constraint; and
when the component is not operating in accordance with the second safety constraint, stop operation of the robotics or automation system.

11. A non-transitory computer-readable storage medium including instructions that, when processed by a computing system cause the computing system to perform operations comprising:
receiving a safety requirements specification, the safety requirements specification defining safety constraints based on user requirements and standards associated with a robotics or automation system;
during design of the robotics or automation system, receiving a selection, by an ontology and reasoning engine, indicative of a component associated with a design of the robotics or automation system;
based on the component and the safety constraints, the ontology and reasoning engine determining one or more safety aspects associated with the component;
the ontology and reasoning engine receiving at least one decision related to the one or more safety aspects associated with the component; and
based on the at least one decision, the ontology and reasoning engine updating an ontology associated with the component.

12. The computer-readable storage medium as recited in claim 11, the operations further comprising:
responsive to the at least one decision, imposing a first safety constraint on an implementation module, the implementation module configured to implement the design of the robotics or automation system.

13. The computer-readable storage medium as recited in claim 12, the operations further comprising:
during implementation of the design of the robotics or automation system, based on the first safety constraint, the implementation module calling a function to determine whether a physical device associated with the component is working in accordance with the first safety constraint.

14. The computer-readable storage medium as recited in claim 13, the operations further comprising:
during implementation of the design of the robotics or automation system, making a determination that the physical device associated with the component is not working in accordance with the first safety constraint; and
based on the determination, imposing a second safety constraint on a design module, the second safety constraint associated with the component,
wherein the design module is configured to generate the design of the robotics or automation system.

15. The computer-readable storage medium as recited in claim 14, the operations further comprising:
during operation of the robotics or automation system, determining whether the component is operating in accordance with the second safety constraint; and
when the component is not operating in accordance with the second safety constraint, stopping operation of the robotics or automation system.
